(19) United States
(12) Patent Application Publication
(10) Pub. No.: US 2015/0276885 A1
(43) Pub. Date: Oct. 1, 2015

(54) Method of Computing State of Charge and Battery State of Charge Monitor

(71) Applicant: STMicroelectronics International N.V., Amsterdam (NL)

(72) Inventors: Hariharasudhan K.R., Noida (IN); Ramkumar S., Noida (IN)

(73) Assignee: STMICROELECTRONICS INTERNATIONAL N.V., Amsterdam (NL)

(21) Appl. No.: 14/225,192

(22) Filed: Mar. 25, 2014

(51) Int. Cl. G01R 31/36

(52) U.S. Cl. CPC G01R 31/3648; G01R 31/3606

(57) ABSTRACT

Disclosed herein are a method of computing an estimated SOC and a battery state of charge (SOC) monitor. An embodiment method for computing an estimated SOC includes periodically measuring a present battery current and a present battery voltage. A hysteresis compensation value is then computed based on a previous SOC, the present battery current, and the present battery voltage when a change in battery current exceeds a threshold. The estimated SOC is then determined based on the hysteresis compensation value and a baseline SOC determined based on the present battery voltage and the present battery current.

### TECHNICAL FIELD

This invention relates generally to battery state of charge (SOC) and, in specific embodiments, to a technique for computing battery SOC and a battery SOC monitor.

### BACKGROUND

Mobile devices are increasingly prevalent in peoples' day-to-day activities. Traditional land-line telephones are being dropped in favor of mobile phones and smart phones, although many people remain on land-line service. Many of those who insist on land-line service utilize cordless phones. Many desktop computers are being replaced by laptop and tablet computers or other slim-profile portable alternatives. In the gaming industry, where console systems once dominated, mobile handheld platforms are becoming more popular. Similarly, in the healthcare industry, devices and equipment that were once tethered to the wall by power and data cables, are becoming increasingly portable. Thermometers have long been portable, but they've become more intelligent and can provide data that most relied on doctor visits to obtain. Likewise, glucose meters, blood-pressure cuffs, pulse oximeters, pedometers, scales, medication tracking, and even fitness equipment, among others, are available in portable alternatives.

Hundreds of millions of mobile devices ship to consumers each year; and industries expect the trend to continue and possibly accelerate. Mobile networks reach further into previously unserviceable areas, and providers continuously expand their bandwidth on existing networks. In the healthcare industry, an aging population will likely be a boon to the medical device sector. Additionally, the number of individuals with diagnosed chronic conditions is continuously rising, along with a strengthening initiative to provide treatment. Mobile medical devices and equipment allow the healthcare industry to distribute services in a cost effective and a more personalized manner.

Technology is typically the primary limitation on mobile devices and mobile services. One particularly critical aspect of mobile technology is power and, more specifically, batteries. Battery technology often dictates the size and possibly even the ultimate utility in a mobile device. Large batteries are bulky and heavy, while smaller batteries often lack endurance. The time to charge often varies among battery types, making some suitable for certain applications and unsuitable for others.

### SUMMARY OF THE INVENTION

Embodiments of the present invention provide a method of computing an estimated state of charge (SOC) for a battery and a battery SOC monitor.

An embodiment method of computing an estimated SOC for a battery includes periodically measuring a present battery current (Ibat) and a present battery voltage (Vbat). A hysteresis compensation value is then computed based on a previous SOC, the present that, and the present Vbat when a change in that exceeds a threshold. The estimated SOC is then determined based on the hysteresis compensation value and a baseline SOC determined based on the present Vbat and the present that.

An embodiment battery SOC monitor includes a meter coupled to a processor. The meter is configured to periodically measure an that and a Vbat for a battery. The processor is configured to receive a present that and a present Vbat for a present period. When a change in the that exceeds a threshold, the processor is further configured to compute a depth of charge/discharge based on a previous that and a charge/discharge duration. When the threshold is exceeded, the processor is also configured to compute a hysteresis compensation time based on a previous SOC and the depth of charge/discharge, and to compute a hysteresis compensation value based on the previous SOC, the present that and the present Vbat. The processor then determines an estimated SOC based on the hysteresis compensation value and a baseline SOC. The baseline SOC is determined based on the present Ibat and the present Vbat. The processor is further configured to reduce and apply the hysteresis compensation value over the hysteresis compensation time.

The details of one or more embodiments of the invention are set forth in the accompanying drawings and the description below. Other features and advantages of the invention will be apparent from the description and drawings, and from the claims.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 is a block diagram of one embodiment of a battery management system;

FIG. 2 is a block diagram of one embodiment of a battery SOC monitor;

FIG. 3 is a plot of a charging SOC curve and a discharging SOC curve illustrating charge/discharge hysteresis;

FIG. 4 is a schematic of an equivalent circuit for a battery;

FIG. 5 is a flow diagram of one embodiment of a method of computing an SOC for a battery; and

FIG. 6 is a flow diagram of another embodiment of a method of computing an SOC for a battery.

Corresponding numerals and symbols in different figures generally refer to corresponding parts unless otherwise indicated. The figures are drawn to clearly illustrate the relevant aspects of embodiments of the present invention and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

The making and using of embodiments are discussed in detail below. It should be appreciated, however, that the present invention provides many applicable inventive concepts that may be embodied in a wide variety of specific contexts. The specific embodiments discussed are merely illustrative of specific ways to make and use the invention, and do not limit the scope of the invention.

Mobile devices often include a battery management feature. Battery management allows a mobile device to charge and discharge its battery, as well as estimate its battery's state of charge (SOC). SOC indicates a predicted remaining battery capacity. A variety of actions can be taken according to a mobile device's SOC, typically in an effort to extend the life of a battery charge when the predicted remaining battery capacity is low, and to take advantage of excess power when the predicted remaining battery capacity is high. For example, processing rates for a microprocessor can be reduced to conserver power. Another example is to reduce data rates over communication channels to conserve power. Conversely, if SOC indicates the estimated remaining battery capacity is high, processing rates and data rates can be held at current rates to maintain current power consumption, or increased to achieve performance gains. Additionally, the SOC is an important indicator to a user of the mobile device for determining when to charge the mobile device's battery.

There are a variety of techniques available for determining a battery's SOC, including coulomb counting and open circuit voltage (VOC) correlations. It is realized herein that these techniques can be accurate at the expense of power consumption and cost. It is further realized herein that the SOC at a given point in time varies greatly according to charge/discharge hysteresis. For a given VOC for a battery, the SOC can be determined according to a known correlation between VOC and SOC for the battery.

However, it is realized herein the correlation contains hysteresis according to charge and discharge cycles experienced since the battery's last complete charge or complete discharge. For example, a battery at 50% capacity would have a higher VOC during a charge cycle than during a discharge cycle. The difference in VOC between a charge cycle and discharge cycle further varies according to parameters of preceding charge and discharge cycles, and therefore complicates drawing a correlation to an estimated SOC.

It is realized herein the parameters that impact the VOC-SOC correlation include charge/discharge current, time of charge and discharge, and any relaxation period that may exists between charge and discharge cycles. It is also realized herein that to estimate a battery's SOC, the charge/discharge hysteresis should be accounted for. Additionally, the relationship between VOC and SOC is typically non-linear.

It is realized herein the charge/discharge hysteresis can be compensated for based on periodic measurements of battery charge/discharge current and battery voltage. The period of these measurements varies per implementation, depending greatly on the particular device and battery used. For example, one embodiment can make measurements every 10 seconds, while another measures every 100 seconds, and yet another measures every second. More frequent measurements can impact power consumption of the battery management system, which should be balanced with the benefits provided. It is also realized herein the period of the measurements can insulate the hysteresis compensation from high-frequency changes in charge/discharge current and battery voltage.

It is realized herein the battery charge/discharge current can be used in combination with a duration of charge/discharge to estimate a depth of charge/discharge. Additionally, battery charge/discharge current can be used to further compensate for voltage drop across the battery's internal resistance, which is typically known for a given battery. When measured battery current indicates a change in battery current, it is realized herein, the VOC-SOC correlation experiences hysteresis that can be compensated for over a period of time. The amount of compensation is referred to as a hysteresis compensation value and the period of time over which the hysteresis compensation value is applied is referred to as a hysteresis compensation time, which are functions of battery voltage, the depth of charge/discharge, the current estimated SOC, and the change in battery current.

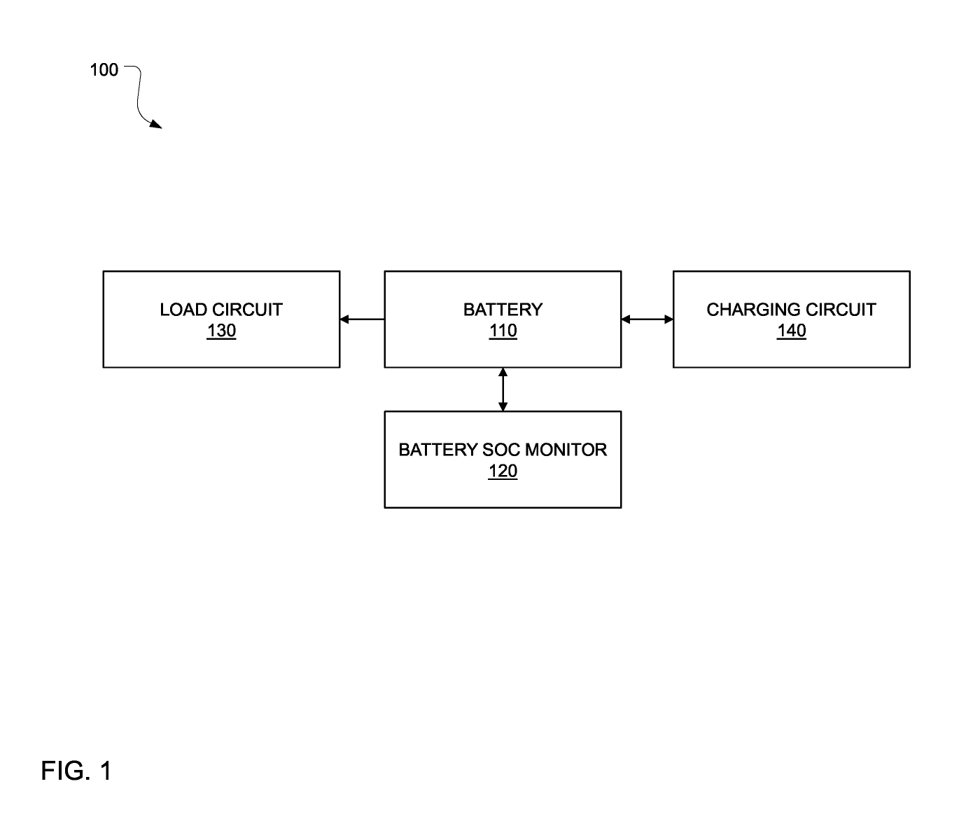

FIG. 1 is a block diagram of a battery management system 100 within which the battery SOC monitor or method of computing a battery SOC introduced herein may be embodied or carried out. Battery management system 100 includes a battery 110, a battery SOC monitor 120, a load circuit 130, and a charging circuit 140. Load circuit 130 is any electrical circuit configured to be powered by battery 110. Mobile devices include a wide variety of load circuits, including communications circuits, processing circuits, display circuits, and many others. Charging circuit 140 is responsible for restoring energy to battery 110. A basic charging circuit is operable to transfer grid-power, which is typical household power, for example, 120 volt and 60 hertz in the United States, into battery 110. Voltage and frequency of grid-power can vary among countries. Certain embodiments of charging circuit 140 include an AC to DC converter for charging battery 110. Battery 110 has an SOC that can be determined according to a correlation between its VOC and SOC. Additionally, battery 110 also has an internal resistance.

Battery SOC monitor 120 is configured to monitor battery currents flowing from battery 110 to load circuit 130 and from charging circuit 140 to battery 110. Battery SOC monitor 120 uses the battery current and battery voltage to compensate for charge/discharge hysteresis in the VOC-SOC correlation for battery 110. Battery SOC monitor 120 applies the compensation over a period of time and determines an SOC accordingly.

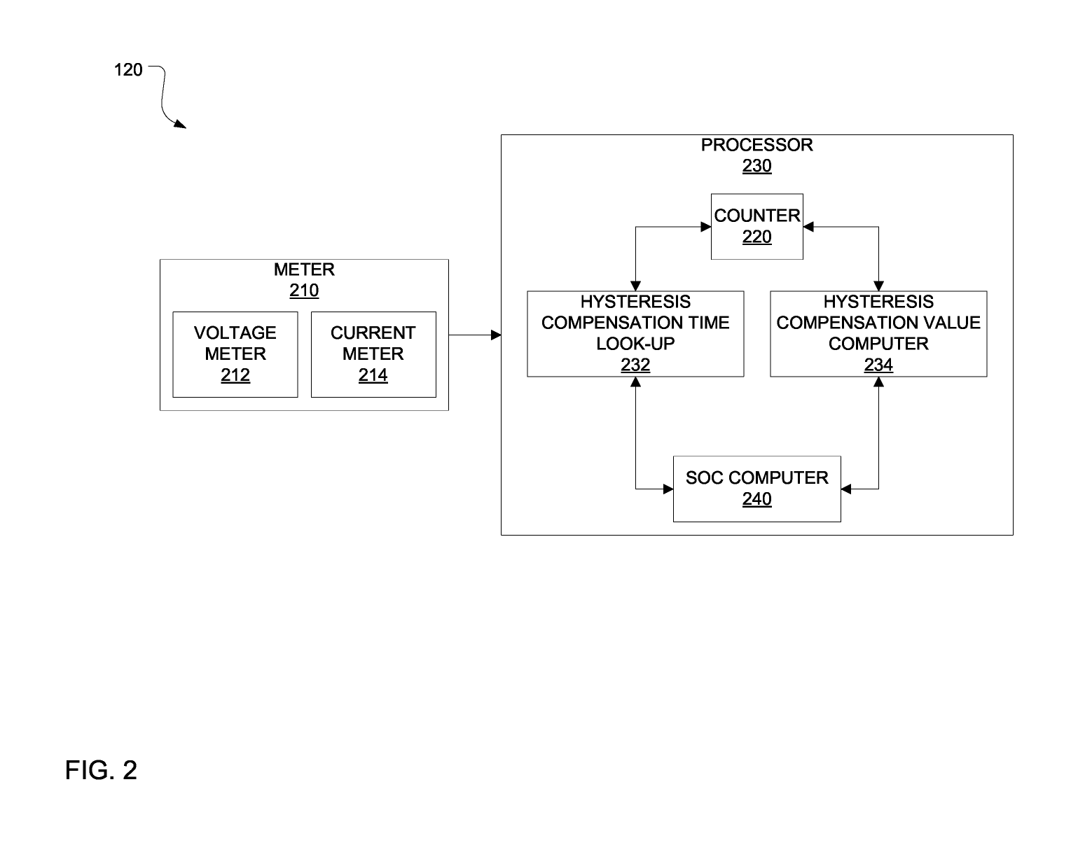

FIG. 2 is a functional block diagram of one embodiment of battery SOC monitor 120 of FIG. 1. Battery SOC monitor 120 includes a meter 210 and a processor 230. Within processor 230 is a counter 220, hysteresis compensation time look-up module 232, a hysteresis compensation value computer 234, and an SOC computer 240. These components can be individual hardware blocks or can be implemented by processor code operating on the processor, or a combination thereof. The processor code would be stored on a memory, which is not shown, the is coupled to the processor.

Meter 210 includes a voltage meter 212 and a current meter 214. Voltage meter 212 is configured to periodically measure battery voltage (Vbat), and current meter 214 is configured to periodically measure battery current (that). For example, assume periodic measurements at a time T are Vbat(T) and Ibat(T), and that the time period between measurements is T_{Δ}. If at time T the battery ends a charge cycle that charged with a battery current of 100 mA for T seconds, then Ibat(T) would be zero, and Ibat(T−T_{Δ}) would be 100 ma. Battery voltage would also begin to drop as the charge cycle ends, so Vbat(T)<Vbat(T−T_{Δ}).

Processor 230 receives the present battery voltage and present battery current from meter 210, monitoring for changes in battery current that rise above a threshold. The threshold can be specified according to a particular application of battery SOC monitor 120. For example, one embodiment may use a threshold of 10-50 milliamp (mA). While it is not generally more than that, embodiments can be envisioned where the threshold is up to 100 mA or more. This parameter can be fixed or in can be configurable. The specific value will result in a trade off in the accuracy of SOC measurement.

As changes in battery current remain below the threshold, the current VOC-SOC correlation is maintained with no additional compensation necessary for charge/discharge hysteresis. When a change in battery current rises above the threshold, processor 230 recognizes the change as cause for hysteresis in the VOC-SOC correlation. The change in battery current generally indicates a shift from one charge cycle or discharge cycle to another. Processor 230 generates a time of charge/discharge via counter 220. The time of charge/discharge begins at the previous shift from one charge or discharge cycle to the current charge or discharge cycle, and ends upon the recognition of the change in battery current that rises above the threshold. Processor 230 computes a depth of charge/discharge based on the present battery current and the time of charge/discharge. For example, in one embodiment, depth of charge/discharge is the product of the present battery current and the time of charge/discharge.

Hysteresis compensation time look-up module 232 uses the computed depth of charge/discharge and the previous SOC estimated at the previous shift from one charge or discharge cycle to the current charge or discharge cycle to determine a hysteresis compensation time, which is the time period over which a hysteresis compensation value is applied. For example, in certain embodiments, a given compensation value can be applied over the course of N measurement intervals. If the hysteresis compensation time is 100 seconds and the measurement interval is 10 seconds, then the hysteresis compensation value is applied over 10 measurement intervals, the applied hysteresis compensation value being smaller at each subsequent measurement interval. The given compensation value can be applied exponentially over the N sampling intervals, or in other embodiments, applied such that the compensation value applied at each interval decreases linearly. The hysteresis compensation time is determined by hysteresis compensation time look-up module 232 according to a table-look up of pre-computed compensation times. The pre-computed compensation times are derived according to previous charge/discharge current, charge/discharge time, and the position on the charge/discharge SOC curve.

Hysteresis compensation value computer 234 uses the present battery voltage, the present battery current, and the previous SOC to compute the hysteresis compensation value. The hysteresis compensation value is the difference between a baseline SOC and the previous SOC. The baseline SOC is computed by SOC computer 240 according to the present battery voltage and the present battery current. The baseline SOC represents an SOC drawn from a correlation between VOC and SOC, and is uncompensated for charge/discharge hysteresis. VOC is derived from the present battery voltage by reducing it based on the present battery current through a known internal battery resistance. In alternative embodiments, SOC computer 240 can also include a variety of other parameters in its estimation of battery VOC, including battery age, temperature, resting period, and others.

SOC computer 240 uses three curves to describe the relationship between VOC and SOC: a relaxed battery curve, a charging battery curve, and a discharging battery curve. SOC computer 240 selects the appropriate curve according to the battery current for a given baseline SOC computation. For example, a zero current indicates the battery is in a relaxed state, a negative current indicates a discharge cycle, and a positive current indicates a charge cycle. In certain embodiments, the three curves are represented by a look-up table indexed by VOC and battery current. In other embodiments, the three curves are represented as three functions of VOC and battery current. In alternative embodiments, the compensation for voltage drop across the internal resistance of the battery is built into the look-up table or the three curve functions; in those embodiments the look-up table would be indexed by the battery voltage rather than VOC, or the three curves would be defined by functions of battery voltage rather than VOC.

The previous SOC is the previous estimate SOC and includes compensation for any past charge/discharge hysteresis. SOC computer 240 computes estimate SOCs based on battery voltage, battery current, hysteresis compensation value, and hysteresis compensation time. The previous estimate SOC is determined by computing a baseline SOC according to the previous battery voltage and previous battery current, as described above, and adding the previous hysteresis compensation value.

Continuing the example above at time T, the hysteresis compensation value is computed as a baseline SOC at time T minus the estimated SOC for time T−T_{Δ}. The baseline SOC for time T is a function of Vbat(T) and Ibat(T). The estimated SOC for time T−T_{Δ} is computed by adding the previous hysteresis compensation value to a baseline SOC for time T-T_{Δ}. The baseline SOC for time T−T_{Δ} is a function of Vbat(T−T_{Δ}) and Ibat(T−T_{Δ}).

SOC computer 240 is further configured to apply the hysteresis compensation value computed by hysteresis compensation value computer 234 over the hysteresis compensation time computed by hysteresis compensation time look-up module 232. The hysteresis compensation value is applied by adding it to a baseline SOC, which is determined according to the present battery current and the present battery voltage. The hysteresis compensation value is also applied to subsequent estimate SOCs according to the hysteresis compensation time. The hysteresis compensation value is reduced for each subsequent estimate SOC.

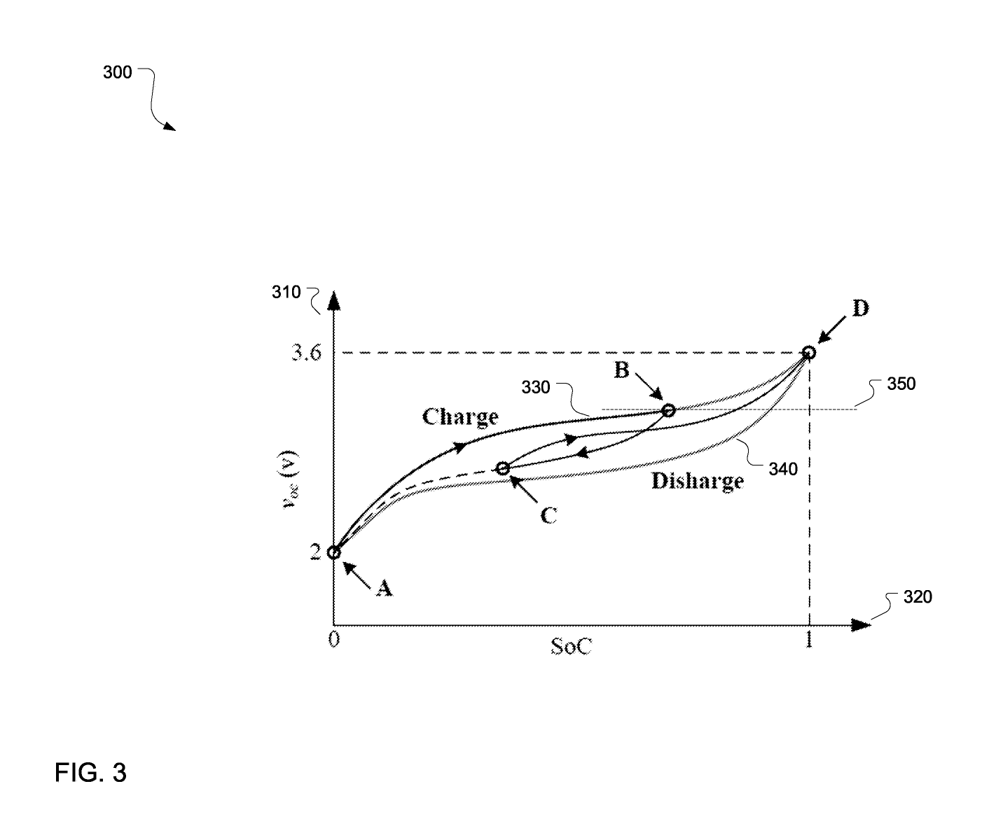

FIG. 3 is a plot 300 of a charging SOC curve and a discharging SOC curve illustrating charge/discharge hysteresis. Plot 300 includes a horizontal SOC axis 320 and a vertical VOC axis 310. Plot 300 illustrates a correlation between VOC of a battery and the battery's SOC. The correlation is not a single curve, but a family of curves bound by a charge curve 330 and a discharge curve 340. The family of curves illustrate hysteresis in the correlation between VOC and SOC based on charge/discharge history. Generally, a relaxed-battery curve exists between charge curve 330 and discharge curve 340, approximating the correlation of VOC and SOC when the battery is in a relaxed state. This plot can be determined, for example, through experimentation for a given battery or battery type.

For example, assume a completely discharged battery at a point A, which correlates a SOC of zero to a VOC of 2 volts. At point A there is a one-to-one correlation of VOC and SOC. As the battery charges from an SOC of zero, the correlation assumes the charge curve 330 until a point B. At point B, the charge cycle ends and a discharge cycle begins. At point B, plot 300 illustrates the charge/discharge hysteresis in the correlation of VOC and SOC. Given a VOC at point B, the family of curves bound by charge curve 330 and discharge curve 340 define a range of values for SOC, the range defined by the horizontal space between charge curve 330 and discharge curve 340 along a reference line 350. To arrive at the SOC for point B, one can consider the charge/discharge history leading up to point B. In the example illustrated in FIG. 3, the charge/discharge history indicates the battery had been charged from point A along charge curve 330 until the charge cycle was ended at point B.

Continuing the example of FIG. 3 from point B, the discharge cycle extends to a point C, where the battery transitions back to a charge cycle. The discharge cycle causes a voltage drop for both the battery voltage and the VOC. Once again, the charge/discharge history indicates the discharge cycle was from point B, corresponding to a particular SOC at a particular VOC on charge curve 330. Given battery voltage and battery current measurements since point B, an SOC at point C can be determined.

Beginning at point C, a charge cycle extends to a complete charge at a point D. Point D correlates an SOC of one to a VOC of 3.6 volts, which is a one-to-one correlation.

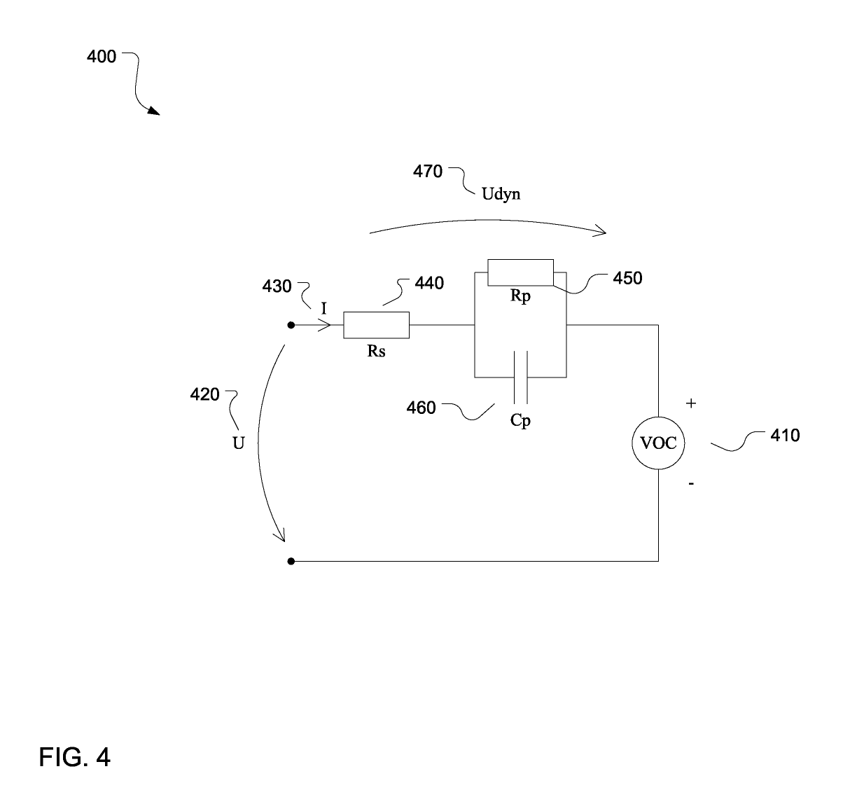

FIG. 4 is a schematic of one embodiment of an equivalent circuit 400 for a battery. Given that SOC is a function of the VOC, an equivalent circuit is needed to model the relationship between a battery voltage 420 at its terminals, and a VOC 410. Equivalent circuit 400 assumes a one time constant (OTC) model for the battery. Alternative embodiments can use other models, such as an internal resistance model or a two time constant model. In the embodiment of FIG. 4, equivalent circuit 400 includes a series resistance 440 and an resistance-capacitance (RC) network formed by a parallel resistance 450 and a parallel capacitance 460. The RC network provides a time constant as a function of parallel resistance 450 and parallel capacitance 460.

Battery voltage 420 generates a battery current 430 that flows through series resistance 440 and the RC network. Consequently, a dynamic voltage 470 is applied across the total impedance of series resistance 440 and the RC network, which constitutes a calculable voltage drop and allows computation of VOC 410.

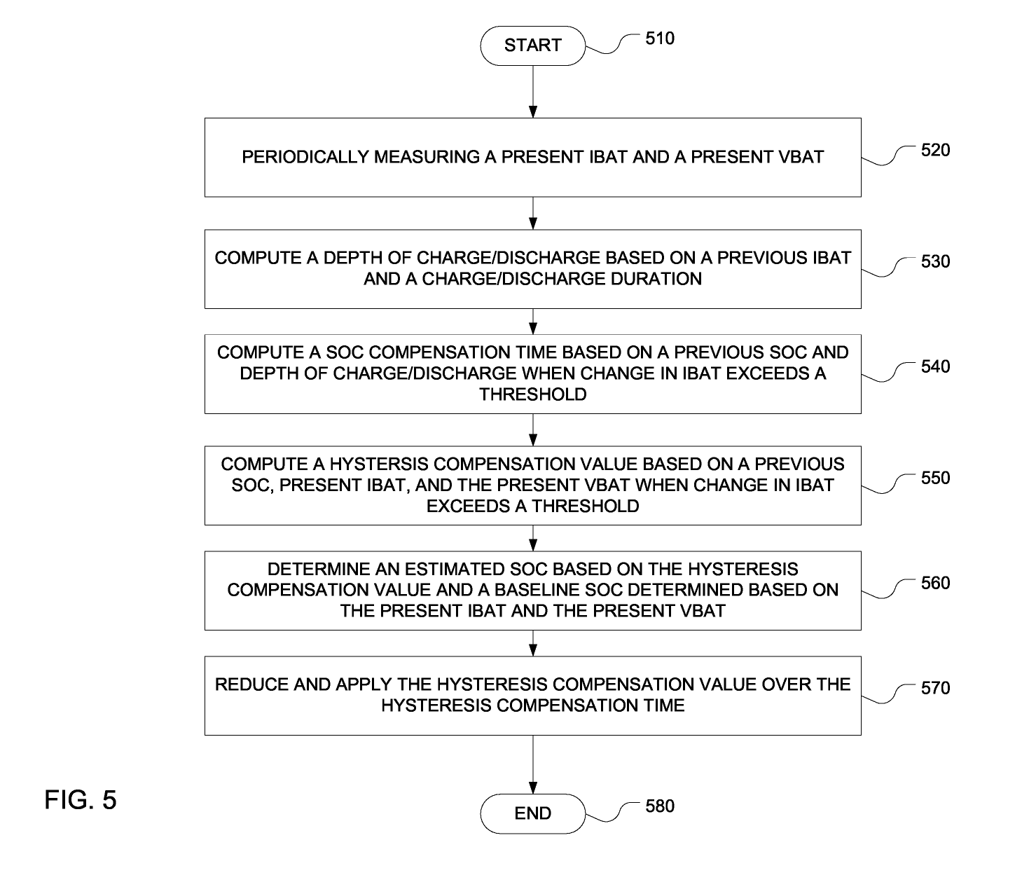

FIG. 5 is a flow diagram of a method of one embodiment of a method of computing an estimated SOC for a battery. The method begins at a start step 510. At a measuring step 520, the battery's current (that) is measured along with a battery voltage (Vbat). that and Vbat measurements are made periodically, thereby guarding against high-frequency changes in battery current. At a first compute step 530, the periodic measurements are used in computing a depth of charge/discharge.

The depth of charge/discharge is used in a second compute step 540 to compute a hysteresis compensation time for charge/discharge VOC-SOC hysteresis. The hysteresis compensation time is the time over which a hysteresis compensation value is applied to the estimated SOC. In certain embodiments the hysteresis compensation time is determined from a look-up table of pre-computed hysteresis compensation times. The look-up table can be indexed by a previous SOC and the depth of charge. In alternative embodiments, the look-up table can also be indexed by the components of the depth of charge, which are the charge/discharge duration and a previous battery current.

At a third compute step 550 the hysteresis compensation value is computed based on a previous SOC, the present Ibat, and the present Vbat. The SOC compensation value is computed when a change in Ibat exceeds a threshold. The threshold can be configurable, allowing for tuning the method to a particular battery and application. For example, in one embodiment, the threshold for change in that is 50 mA or less. In another embodiment, the threshold may be 10 mA. In general, the threshold for triggering hysteresis compensation is typically on the order 10-50 mA. While it is not generally more than that, embodiments can be envisioned where the threshold is up to 100 mA or more.

The hysteresis compensation value from third compute step 550 is then applied at an SOC compute step 560 to determine the estimated SOC. The estimated SOC is computed based on the hysteresis compensation value and a baseline SOC determined based on the present Vbat and the present that. The baseline SOC is determined according to a correlation between SOC and a VOC for the battery. The VOC is determined by compensating Vbat for a voltage drop across the battery's internal resistance, which can be computed based on Ibat and a known internal resistance for the battery. In alternative embodiments, the VOC can be determined according to additional parameters, including age of battery, temperature, and others.

At an updating step 570, the hysteresis compensation value from third compute step 550 is reduced exponentially to zero over the hysteresis compensation time from second compute step 540. In alternative embodiments, the hysteresis compensation value is reduced linearly to zero. Continuing the embodiment of FIG. 5, the reduced hysteresis compensation value is then applied for subsequent determinations of estimated SOC at SOC compute step 560. The method then ends at an end step 580.

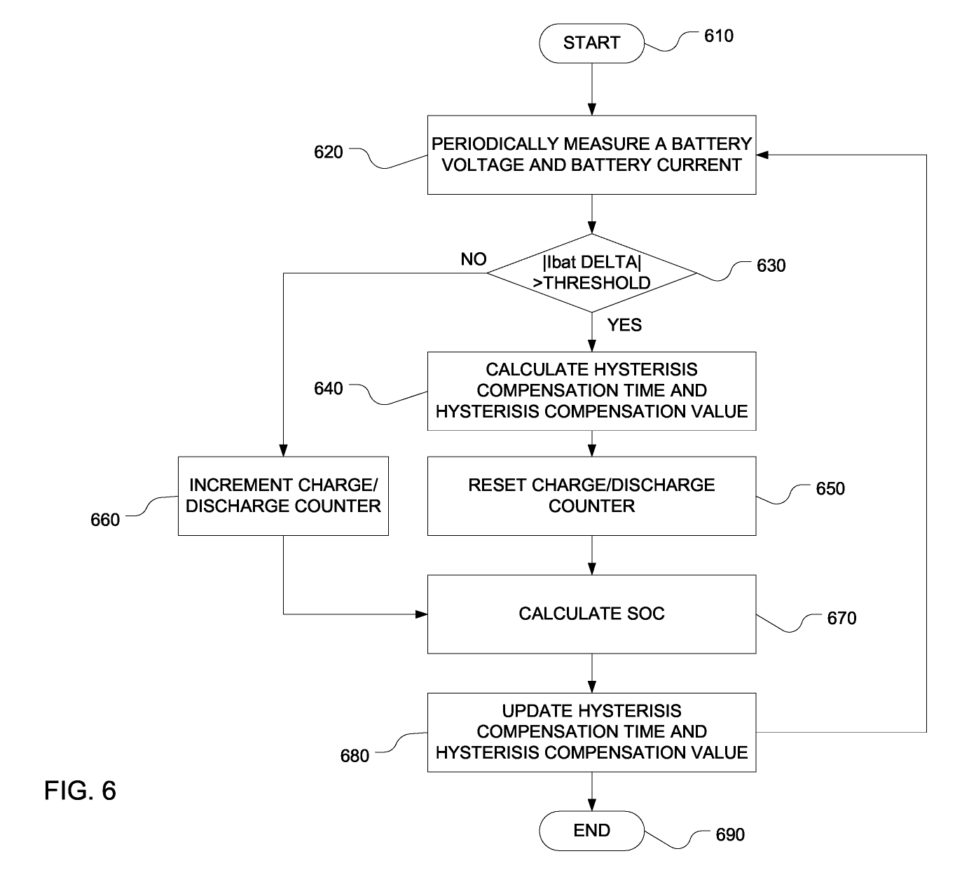

FIG. 6 is a flow diagram of another embodiment of a method of computing an estimate SOC for a battery. The method begins at a start step 610. At a measurement step 620, a battery voltage and a battery current are periodically measured. The period for the measurements is configurable for a given application and for a given battery. For example, the period can be 10 seconds, 20 seconds, 100 seconds, etc. At a threshold checking step 630, the present battery current, which was measured at measurement step 620, is compared to the previous battery current, which was measured in the previous period. If the change in battery current over the period exceeds a threshold, charge/discharge hysteresis compensation is initiated. The change in battery current generally indicates a transition from one charge/discharge cycle to another. The threshold is also configurable to suit the given application and the given battery. For example, the threshold can be 100 mA, 200 mA, 1000 mA, etc. If the threshold is not exceed by the change in battery current, the present charge/discharge cycle is assumed to continue. The duration of the present charge/discharge cycle is tracked at a counting step 660, where the number of periods in the present charge/discharge cycle are counted.

When the change in battery current exceeds the threshold, as determined at threshold checking step 630, a hysteresis compensation value and a hysteresis compensation time are computed at a computation step 640. The hysteresis compensation value is computed as a function of the present battery voltage, the present battery current, and the previous SOC. The present battery voltage and present battery current are used to determine a VOC by compensating the battery voltage for a voltage drop across a known internal resistance of the battery. The present battery current is also indicative of whether the battery is charging, discharging, or is relaxed, allowing a selection of either a charging VOC-SOC curve, a discharging VOC-SOC curve, or a relaxed VOC-SOC curve. Given the selection, the VOC determined according to the present battery voltage and present battery current correlates to a baseline SOC, which includes no compensation for charge/discharge hysteresis. In some embodiments, the correlation is implemented as a one-to-one function for the selected curve. In other embodiments, the correlation is implemented as a look-up table indexed by the VOC. The look-up table can also be indexed by battery voltage and battery current in certain embodiments.

Continuing the embodiment method of FIG. 6, the previous SOC is subtracted from the baseline SOC, which yields a difference that is the hysteresis compensation value. The difference represents the SOC error in the baseline SOC. The previous SOC is computed based on the previous battery voltage, previous battery current, and the preceding SOC.

The hysteresis compensation time is determined according to the previous SOC, the previous battery current, and the duration of the charge/discharge cycle. The previous battery current and the duration of the charge/discharge cycle are used to compute a depth of charge/discharge, which, in certain embodiments, is simply a product of the previous battery current and the duration of the charge/discharge cycle. The hysteresis compensation time can be determined as a function of the previous SOC and the depth of charge/discharge or, in alternative embodiments, can be implemented as a look-up table indexed by the previous SOC and the depth of charge/discharge. The hysteresis compensation time is the time over which the hysteresis compensation value is applied to an estimated SOC. The hysteresis compensation time is expressed as a number of periods or, in alternative embodiments, expressed in seconds.

The embodiment method of FIG. 6 continues to a reset step 650, where the counter for tracking the duration of the charge/discharge cycle is reset. At an SOC computing step 670, the estimated SOC is determined according to the baseline SOC and the hysteresis compensation value. As described in computing step 640, the baseline SOC is determined according to the present battery voltage and present battery current. The estimated SOC is a sum of the baseline SOC and the hysteresis compensation value. SOC computing step 670 is also carried out when the change in battery current does not exceed the threshold, as determined in threshold checking step 630. In that case, no hysteresis compensation value is calculated and the estimated SOC is the baseline SOC plus any previously computed hysteresis compensation. When no previous hysteresis compensation exists, the baseline SOC is the estimated SOC.

At an update step 680, the hysteresis compensation value from computing step 640 is reduced according to the hysteresis compensation time. The updated hysteresis compensation value for subsequent periods is exponentially lower than the original. In alternative embodiments, the reduction of hysteresis compensation value can be done linearly. The updated hysteresis compensation value would constitute previously computed hysteresis at SOC computing step 670 in subsequent periods. For example, assume the hysteresis compensation value computed at compute step 640 was 50 at after a first period, the hysteresis compensation time is 10 periods, and that the change in battery current does not exceed the threshold for the next 10 periods. Under that assumption, over the next 10 periods, no new hysteresis compensation values or hysteresis compensation times will be computed at computing step 640, nor will the counter be reset at reset step 650. However, at SOC computing step 670, the estimated SOC is computed for each period. For the first period, the estimated SOC is the baseline SOC plus the hysteresis compensation value, 50. At update step 680, the hysteresis compensation value, 50, is reduced according to the 10-period hysteresis compensation time. The hysteresis compensation value is reduced exponentially from 50 to zero over those 10 periods. For instance, the reductions may be from 50 to 38, to 32, to 29, and on down to zero. For the second period, no additional hysteresis compensation is computed, but the reduced hysteresis value is carried over from the previous period. The estimated SOC for the second period is the baseline SOC plus 38. Likewise, the estimated SOC for the third period is the baseline SOC plus 32. Ultimately, for the tenth period, the hysteresis compensation value is reduced to zero, or nearly zero, and the estimated SOC is simply the baseline SOC. The method then ends at an end step 690.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of computing an estimated state of charge (SOC) for a battery, the method comprising:
periodically measuring a present battery current and a present battery voltage;
computing a hysteresis compensation value based on a previous SOC, the present battery current, and the present battery voltage when a change in the present battery current exceeds a threshold; and
determining the estimated SOC based on the hysteresis compensation value and a baseline SOC determined based on the present battery voltage and the present battery current.

2. The method of claim 1, further comprising:
computing a depth of charge/discharge based on a previous battery current and a charge/discharge duration;
computing a hysteresis compensation time based on the previous SOC and the depth of charge/discharge when a change in battery current exceeds a threshold; and
reducing and applying the hysteresis compensation value over the hysteresis compensation time.

3. The method of claim 2, wherein computing the depth of charge/discharge comprises calculating a product of the previous battery current and the charge/discharge duration.

4. The method of claim 2, wherein reducing and applying the hysteresis compensation value comprises exponentially reducing the hysteresis compensation value.

5. The method of claim 2, wherein the hysteresis compensation time is determined according to an experimentally derived look-up table indexed by the previous SOC and the depth of charge/discharge.

6. The method of claim 1, wherein the periodically measuring comprises measuring the battery current and the battery voltage every 10 seconds.

7. The method of claim 1, wherein the baseline SOC is determined based on an open circuit voltage (VOC) that is computed based on the battery voltage, an internal resistance for the battery, and the battery current.

8. The method of claim 7, wherein the baseline SOC is determined based on a correlation between the VOC and SOC for the battery.

9. The method of claim 1, wherein computing the hysteresis compensation value includes calculating a difference between the baseline SOC and the previous SOC.

10. The method of claim 1, wherein determining the estimated SOC comprises calculating a sum of the baseline SOC and the hysteresis compensation value.

11. A method of computing an estimated state of charge (SOC) for a battery, the method comprising:
storing information related to a hysteresis relationship between state of charge (SOC) and an open circuit voltage (VOC) for the battery, the relationship being a function of a timing between charge functions and discharge functions of the battery;
determining a hysteresis compensation value based on charging and discharging actions taken on the battery and the hysteresis relationship;
measuring parameters of the battery to determine an uncompensated SOC of the battery; and
calculating the estimated SOC based upon the uncompensated SOC and the hysteresis compensation value.

12. The method of claim 11, wherein measuring the parameters comprises measuring a battery current and a battery voltage of the battery.

13. The method of claim 12, wherein the hysteresis compensation value is determined based on the measured battery current, the measured battery voltage and a previous SOC.

14. The method of claim 13, wherein the hysteresis compensation value is determined when a change in the battery current exceeds a threshold.

15. The method of claim 11, wherein the hysteresis relationship comprises a family of curves that illustrate hysteresis in a correlation between VOC and SOC based on charge/discharge history.

16. The method of claim 11, further comprising determining the hysteresis relationship through experimentation.

17. A battery state of charge (SOC) monitor, comprising:
a meter configured to periodically measure a battery current and a battery voltage for a battery; and
a processor coupled to the meter and configured to receive a present battery current and a present battery voltage for a present period and, when a change in the battery current exceeds a threshold, further configured to:
compute a depth of charge/discharge based on a previous battery current and a charge/discharge duration,
compute a hysteresis compensation time based on a previous SOC and the depth of charge/discharge,
compute a hysteresis compensation value based on the previous SOC, the present battery current and the present battery voltage,
determine an estimated SOC based on the hysteresis compensation value and a baseline SOC determined based on the present battery current and the present battery voltage, and
reduce and apply the hysteresis compensation value over the hysteresis compensation time.

18. The battery SOC monitor of claim 17, wherein the processor includes a hysteresis compensation time look-up table that stores information to index into a plurality of pre-computed hysteresis compensation times according to the previous SOC and the depth of charge/discharge.

19. The batter SOC monitor of claim 17, wherein the processor is configured to generate a product of the previous battery current and the charge/discharge duration to compute the depth of charge/discharge.

20. The battery SOC monitor of claim 17, wherein the processor comprises an SOC look-up module having a charging curve data set, a discharging curve data set, and a relaxed curve data set, and the processor is further configured to:
select a curve among the charging curve data set, the discharging curve data set, and the relaxed curve data set according the present battery current; and
index into a corresponding data set for the selected curve according to the present battery voltage and the present battery current, thereby yielding the baseline SOC.

21. The battery SOC monitor of claim 20, wherein the processor is further configured to index into the corresponding data set for the selected curve according to an open circuit voltage (VOC) computed based on the present battery voltage and the present battery current.

22. The battery SOC monitor of claim 20, wherein the processor further comprises an interpolation module coupled to the SOC look-up module and configured to select two SOC data points nearest the present battery voltage and present battery current data points, and interpolate between the two SOC data points to generate the baseline SOC.

23. The battery SOC monitor of claim 17, wherein the threshold is between ten milliamps and five hundred milliamps.

24. The battery SOC monitor of claim 17, wherein the processor comprises a subtraction module configured to generate a difference between the previous SOC and the baseline SOC to compute the hysteresis compensation value.

25. The battery SOC monitor of claim 17, wherein the processor comprises an addition module configured to generate a sum of the baseline SOC and the hysteresis compensation value to compute the estimated SOC.

26. The battery SOC monitor of claim 17, wherein the processor is further configured to reduce the hysteresis compensation value exponentially over the hysteresis compensation time.

27. An apparatus for computing an estimated state of charge (SOC) for a battery, the apparatus comprising:
a processor coupled to a memory;
wherein the processor is programmed to compute the estimated SOC by:
periodically measuring a present battery current and a present battery voltage;
computing a hysteresis compensation value based on a previous SOC, the present battery current, and the present battery voltage when a change in the present battery current exceeds a threshold; and
determining the estimated SOC based on the hysteresis compensation value and a baseline SOC determined based on the present battery voltage and the present battery current.
